(19) United States
(12) Patent Application Publication
(10) Pub. No.: US 2026/0322907 A1
(43) Pub. Date: Oct. 15, 2026

(54) DISPLAY MODULE AND ELECTRONIC DEVICE

(71) Applicant: Samsung Display Co., LTD., Yongin-si (KR)

(72) Inventor: SUNGYONG KWON, Yongin-si (KR)

(21) Appl. No.: 19/536,548

(22) Filed: Feb. 11, 2026

(30) Foreign Application Priority Data
Apr. 15, 2025 (KR) 10-2025-0048698

(51) Int. Cl. H04M 1/02; G06F 1/16

(52) U.S. Cl. CPC H04M 1/0266; G06F 1/1616; G06F 1/1643

(57) ABSTRACT

A display module includes a display panel, a first protective layer, a sensor, a control unit, a flexible circuit, a second protective layer, a high-adhesion part, and a low-adhesion part. The first protective layer is disposed on the display panel. The sensor is disposed on the display panel not to overlap the first protective layer on a plane. The control unit is disposed on the display panel and electrically connected to the display panel. The flexible circuit is connected to the sensor and the control unit. The second protective layer is disposed on the first protective layer and the sensor to cover the sensor. The high-adhesion part is disposed between the first protective layer and the second protective layer. The low-adhesion part is disposed between the second protective layer and the sensor. The low-adhesion part has an integrated shape.

### CROSS-REFERENCE TO RELATED APPLICATION

This application claims priority to Korean Patent Application No. 10-2025-0048698, filed on Apr. 15, 2025, and all the benefits accruing therefrom under 35 U.S.C. §119, the content of which in its entirety is herein incorporated by reference.

### BACKGROUND

### 1. Field

The present disclosure relates to a display module and an electronic device, and more particularly, to a display module that uses a protective layer to fix a coupling position of a sensor and uses an adhesive part that is removed during a manufacturing process to improve reliability and an electronic device.

### 2. Description of the Related Art

In general, a display device may include a display panel and be manufactured through a module process in which a component for driving and a sensor are attached. Since the display panel is typically extremely thin, even small stepped portion may affect a performance of the display panel and lead to a defect. Recently, various researches have been conducted to solve the above-described limitation.

### SUMMARY

The present disclosure provides a display module having improved reliability.

The present disclosure also provides an electronic device having improved reliability.

An embodiment of the invention provides a display module including: a display panel; a first protective layer; a sensor; a control unit; a flexible circuit; a second protective layer; a high-adhesion part; and a low-adhesion part.

In such an embodiment, the first protective layer is disposed on the display panel.

In such an embodiment, the sensor is disposed on the display panel not to overlap the first protective layer in a plan view.

In such an embodiment, the control unit is disposed on the display panel and electrically connected to the display panel.

In such an embodiment, the flexible circuit is connected to the sensor and the control unit.

In such an embodiment, the second protective layer is disposed on the first protective layer and the sensor to cover the sensor.

In such an embodiment, the high-adhesion part is disposed between the first protective layer and the second protective layer.

In such an embodiment, the low-adhesion part is disposed between the second protective layer and the sensor.

In such an embodiment, the low-adhesion part has an integrated shape.

In an embodiment, the first protective layer may include: a first sub-protective layer; and a second sub-protective layer.

In such an embodiment, the first sub-protective layer may be disposed on at least a portion of the display panel.

In such an embodiment, the second sub-protective layer may be disposed on another portion of the display panel and at least a portion of the first sub-protective layer.

In such an embodiment, the second sub-protective layer may cover an area corresponding to a driver integrated circuit (driver IC) of the display panel in the plan view.

In an embodiment, the display module may further include a cushion layer disposed on the second sub-protective layer.

In such an embodiment, the cushion layer may overlap the area corresponding to the driver IC of the display panel in the plan view.

In an embodiment, the high-adhesion part may contact the second protective layer and at least one selected from the first sub-protective layer and the second sub-protective layer.

In an embodiment, the high-adhesion part may include a first sub-adhesion part and a second sub-adhesion part, which are spaced apart from each other.

In an embodiment, the first sub-adhesion part may contact the first sub-protective layer and the second protective layer.

In such an embodiment, the second sub-adhesion part may contact the second sub-protective layer and the second protective layer.

In an embodiment, the first sub-adhesion part may contact the first sub-protective layer, the second sub-protective layer, and the second protective layer.

In such an embodiment, the second sub-adhesion part may contact the first sub-protective layer and the second protective layer.

In an embodiment, the first sub-adhesion part and the second sub-adhesion part may be spaced apart from each other with the sensor therebetween.

In an embodiment, the high-adhesion part may be disposed on the first protective layer and the second protective layer.

In such an embodiment, the high-adhesion part may have an integrated shape.

In an embodiment, the sensor may be a fingerprint sensor.

In an embodiment, the second protective layer may have a thickness greater than a thickness of the first protective layer.

In an embodiment, the second protective layer may have a thickness of about 100 micrometers (μm) or greater.

In an embodiment, the low-adhesion part may be in contact with the sensor and be not in contact with the display panel.

In an embodiment, the second protective layer may include at least one selected from polyethylene terephthalate (PET), polyethylene (PE), and polyimide (PI).

In such an embodiment, one end of the connector may be connected with the control unit.

In such an embodiment, an opposing end of the connector may protrude from one side of the display panel.

In an embodiment of the invention, a display module includes: a display panel; a first protective layer; a sensor; a control unit; a flexible circuit; a second protective layer; a high-adhesion part; and a low-adhesion part.

In such an embodiment, the first protective layer is disposed on the display panel.

In such an embodiment, the sensor is disposed on the display panel not to overlap the first protective layer in a plan view.

In such an embodiment, the control unit is disposed on the display panel and electrically connected to the display panel.

In such an embodiment, the flexible circuit is connected to the sensor and the control unit.

In such an embodiment, the second protective layer is disposed on the first protective layer and the sensor to cover the sensor.

In such an embodiment, the high-adhesion part is disposed between the first protective layer and the second protective layer.

In such an embodiment, the low-adhesion part is disposed between the second protective layer and the sensor.

In such an embodiment, the second protective layer has a thickness greater than a thickness of the first protective layer.

In an embodiment, the sensor may be a fingerprint sensor.

In an embodiment, the low-adhesion part may be in contact with the sensor and be not in contact with the display panel.

In an embodiment, the second protective layer may have a thickness of about 100 μm or greater.

In an embodiment of the invention, a display module includes: a display panel; a first sub-protective layer; a second sub-protective layer; a sensor; a second protective layer; a high-adhesion part; and a low-adhesion part.

In such an embodiment, the first sub-protective layer is disposed on at least a portion of the display panel.

In such an embodiment, the second sub-protective layer is disposed on another portion of the display panel and at least a portion of the first sub-protective layer.

In such an embodiment, the sensor is disposed on the display panel not to overlap the first sub-protective layer and the second sub-protective layer on a plane.

In such an embodiment, the second protective layer is disposed on the first sub-protective layer, the second sub-protective layer, and the sensor to cover the sensor.

In such an embodiment, The high-adhesion part is disposed between the second protective layer and at least one selected from the first sub-protective layer and the second sub-protective layer.

In such an embodiment, the low-adhesion part is disposed between the second protective layer and the sensor.

In such an embodiment, the low-adhesion part has an integrated shape.

In an embodiment, the sensor may be a fingerprint sensor.

In such an embodiment, the second sub-protective layer may cover an area corresponding to a driver IC of the display panel in the plan view.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view illustrating a display device according to an embodiment;

FIG. 2 is a cross-sectional view illustrating a display panel according to an embodiment;

FIG. 3 is a plan view illustrating a display module according to an embodiment;

FIG. 4 is a cross-sectional view taken along line I-I’ of FIG. 3;

FIG. 5 is a plan view illustrating a display module according to an embodiment;

FIG. 6 is a plan view illustrating a display module according to an embodiment;

FIG. 7 is a plan view illustrating a display module according to an embodiment;

FIG. 8 is a plan view illustrating a display module according to an embodiment;

FIG. 9 is a block diagram illustrating an electronic device according to an embodiment; and

FIG. 10 is schematic views illustrating electronic devices according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, it will be understood that when one component (or region, layer, portion) is referred to as being ‘connected to’, or ‘coupled to’ another component, it can be directly connected/coupled on/to the one component, or an intervening third component may also be present.

Like reference numerals refer to like elements throughout. Also, in the figures, the thickness, ratio, and dimensions of components are exaggerated for clarity of illustration.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the present specification, if an embodiment can be implemented in different ways, specific process steps may be performed in an order different from that described. For example, two consecutively described steps may be performed substantially simultaneously, or in a reverse order from that described.

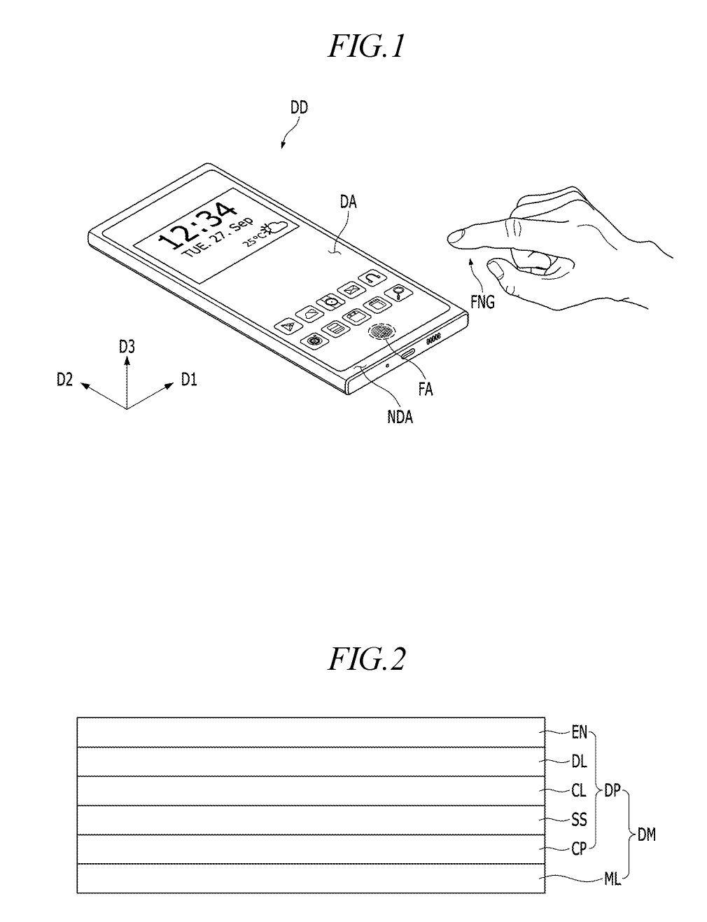

First to third directions DR1, DR2, and DR3 may be defined. The first direction DR1 and the second direction DR2 that are directions defined on a plane of a display device DD illustrated in FIG. 1 may cross each other. The third direction DR3 may be a thickness direction of the display device DD, which is defined in FIG. 2.

In the present specification, an expression "on the plane" or “in a plan view” may refer to a direction viewed from the third direction DR3, i.e., a direction looking from an upper side to a lower side of a component. In addition, the descriptions in the present specification based on a specific direction may encompass not only the direction shown in the drawings but also the opposite direction thereto.

Hereinafter, embodiments of the invention will be described with reference to the accompanying drawings. Identical or corresponding components are denoted by the same reference numerals, and redundant descriptions thereof will be omitted.

FIG. 1 is a perspective view illustrating a display device according to an embodiment.

Referring to FIG. 1, the display device DD according to an embodiment may include a display area DA and a non-display area NDA disposed on at least one side of the display area DA.

The display area DA is a portion on which an image is displayed, and a plurality of pixels PX may be disposed thereon. Although an embodiment where the display area DA has a rectangular shape with rounded corners is shown in FIG. 1, the embodiment of the invention is not limited thereto. In an embodiment, for example, the display area DA may have various shapes such as a circular, elliptical, and polygonal shape, or a specific figure shape.

A sensing area FA may be defined on one side of the display area DA. The sensing area FA may be an area for sensing fingerprint information from a finger FNG of a user. The sensing area FA may be an area corresponding to a sensor FS that will be described later.

Various lines that transmit electrical signals applied to the display area DA may be disposed on the non-display area NDA.

Hereinafter, an organic light-emitting display device will be described as an example of the display device DD according to an embodiment of the invention. However, the embodiment of the invention is not limited thereto. In another embodiment, the display device DD according to an embodiment of the invention may be an inorganic light-emitting display device or a quantum dot light-emitting display device. In an embodiment, for example, a light-emitting layer of a display element of the display device DD may include an organic material, an inorganic material, a quantum dot, both an organic material and a quantum dot, or both an inorganic material and a quantum dot.

FIG. 2 is a cross-sectional view illustrating a display panel according to an embodiment.

According to an embodiment, a display panel DP may include a cover panel CP, a substrate SS, a circuit layer CL, a display layer DL, and an encapsulation layer EN.

The cover panel CP may be disposed at a lower end (on a lower surface) of the display panel DP. The cover panel CP may protect the display panel DP from external impact or reduce an effect of heat on the display panel DP. In an embodiment, for example, the cover panel CP may include at least one selected from a sponge, a plastic panel, a metal panel, and a heat dissipation film.

The substrate SS may include or be made of at least one selected from various materials such as glass, metal, or plastic. In an embodiment, the substrate SS may be a flexible substrate. In an embodiment, for example, the substrate SS may include a polymer resin such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

The circuit layer CL may be disposed on the substrate SS. The circuit layer CL may include transistors (not shown) that apply electrical signals to light-emitting elements (not shown) of the display layer DL and insulating layers (not shown).

Light-emitting elements each including at least one light-emitting layer and a pixel defining layer for distinguishing pixels may be disposed on the display layer DL.

The encapsulation layer EN may be disposed on the display layer DL. The encapsulation layer EN may include at least one inorganic encapsulation layer and at least one organic encapsulation layer. The encapsulation layer EN may protect the display layer DL from external moisture or contaminants.

According to an embodiment, the display module DM may include a display panel DP and a module layer ML. The module layer ML may be disposed on the display panel DP, and more particularly, on the cover panel CP disposed on a rear surface of the display panel DP. Detailed features of the module layer ML will be described later.

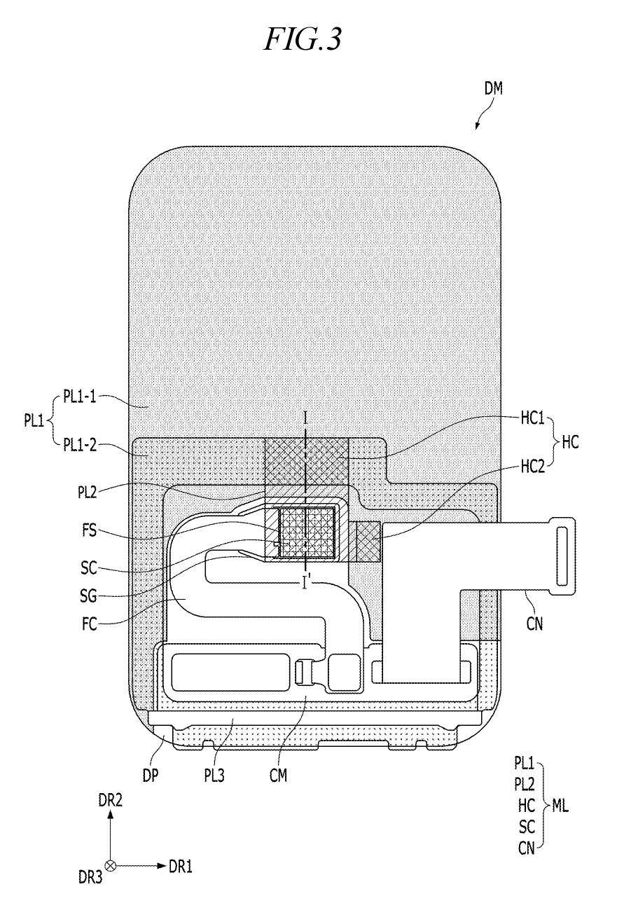

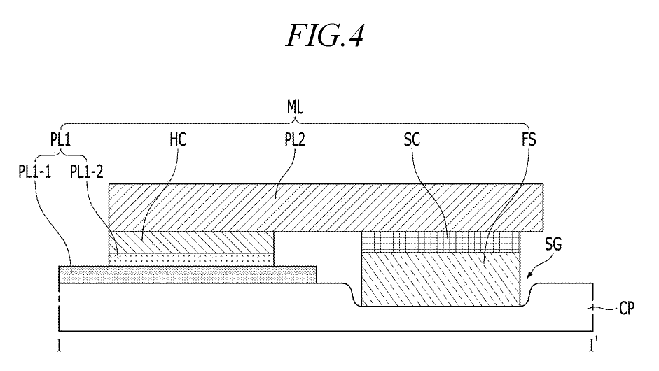

FIG. 3 is a plan view illustrating a display module according to an embodiment. FIG. 4 is a cross-sectional view taken along line I-I’ of FIG. 3.

Referring to FIGS. 3 and 4, the display module DM according to an embodiment may include a display panel DP and a module layer ML. The module layer ML may include a first protective layer PL1, a sensor FS, a control unit CM, a flexible circuit FC, a second protective layer PL2, a low-adhesion part SC, a high-adhesion part HC, and a connector CN.

It may be understood in an embodiment of the invention that the display module DM includes the display panel DP and the module layer ML. The display device DD (refer to FIG. 1) may be formed by removing the first protective layer PL1, the second protective layer PL2, the low-adhesion part SC, the high-adhesion part HC, and the connector CN from the display module DM and then coupling additional components thereto. The first protective layer PL1, the second protective layer PL2, the low-adhesion part SC, the high-adhesion part HC, and the connector CN, which are components that temporarily protect the sensor FS and the display panel DP or components that are temporarily attached, may not be contained in the display device DD (refer to FIG. 1).

The first protective layer PL1 may be disposed on the display panel DP to cover a portion of the display panel DP. The first protective layer PL1 may include a first sub-protective layer PL1-1 and a second sub-protective layer PL1-2.

The first sub-protective layer PL1-1 may be disposed on at least a portion of the display panel DP to cover a portion of the display panel DP. The first sub-protective layer PL1-1 may be attached to the display panel DP to protect a portion of the display panel DP from foreign substances or external impacts. The first sub-protective layer PL1-1 may be a component that is removed from the display panel DP during a process for manufacturing the display device DD (refer to FIG. 1).

The second sub-protective layer PL1-2 may be disposed on the portion of the display panel DP on which the first sub-protective layer PL1-1 is disposed, another portion of the display panel DP, and at least a portion of the first sub-protective layer PL1-1. The second sub-protective layer PL1-2 may be attached to the first sub-protective layer PL1-1 and a portion of the display panel DP. The second sub-protective layer PL1-2 may protect a portion of the display panel DP from foreign substances or external impacts.

In an embodiment, the second sub-protective layer PL1-2 may cover an area corresponding to a driver integrated circuit (driver IC) (not shown) of the display panel DP.

The display module DM according to an embodiment may further include a cushion layer PL3 disposed on the second sub-protective layer PL1-2. The cushion layer PL3 may overlap the area corresponding to the driver IC (not shown) on the plane (in a plan view or in the third direction DR3) to protect components disposed therebelow such as the driver IC (not shown) from external impacts.

In an embodiment, the second sub-protective layer PL1-2 may be a component that is removed from the display panel DP together with the first sub-protective layer PL1-1 during the process for manufacturing the display device DD (refer to FIG. 1).

The sensor FS may be disposed on the display panel DP and may not overlap the first protective layer PL1. The sensor FS may be a fingerprint sensor disposed at a position corresponding to the sensing area FA (refer to FIG. 1) of the display device DD to sense the fingerprint information of the user.

In an embodiment, the cover panel CP may include a seating groove SG.

The sensor FS may be disposed in the seating groove SG of the display panel DP.

The control unit CM may be electrically connected to the sensor FS through the flexible circuit FC to receive the fingerprint information of the user from the sensor FS. In an embodiment, the control unit CM may include a main circuit board for controlling driving of the display panel DP, and the connector CN that will be described later may be connected thereto.

The second protective layer PL2 may be disposed on the first protective layer PL1 and the sensor FS. The second protective layer PL2 may protect the sensor FS from foreign substances or external impacts. Also, the second protective layer PL2 may be attached to the first protective layer PL1 through a high-adhesion part HC to be fixed in position and temporarily attached to the sensor FS through a low-adhesion part SC to fix a position of the sensor FS. Detailed features thereof will be described later.

According to an embodiment, the second protective layer may include at least one selected from polyethylene terephthalate (PET), polyethylene (PE), and polyimide(PI).

In an embodiment, the second protective layer PL2 may cover the sensor FS.

In an embodiment, the second protective layer PL2 may be a component that is removed from the display panel DP together with the first protective layer PL1 during the process for manufacturing the display device DD (refer to FIG. 1).

The high-adhesion part HC may be disposed between the first protective layer PL1 and the second protective layer PL2. The second protective layer PL2 may be coupled to the first protective layer PL1 by the high-adhesion part HC to be fixed in position.

The low-adhesion part SC may be disposed between the sensor FS and the second protective layer PL2. During the process for manufacturing the display device DD (refer to FIG. 1), the sensor FS may be attached to the second protective layer PL2 to be coupled to the cover panel CP of the display panel DP. That is, the sensor FS and the second protective layer PL2 may be temporarily coupled to each other with low strength through the low-adhesion part SC. Here, since the second protective layer PL2 is fixed in position by the first protective layer PL1 and the high-adhesion part HC, the sensor FS that is coupled to the second protective layer PL2 may be also fixed in position. The low-adhesion part SC and the second protective layer PL2 may be components that are removed after the sensor FS is permanently coupled to the cover panel CP. Thus, the display device DD (refer to FIG. 1) according to an embodiment of the invention may not include a component for temporary coupling on the sensor FS.

In an embodiment of the invention, the low-adhesion part SC and the high-adhesion part HC may serve to temporarily fix a position of the sensor FS before a curing process for permanent coupling of the display panel DP and the sensor FS is performed. According to an embodiment, the sensor FS may be an ultrasonic sensor, and an autoclave process for removing an air gap between the sensor FS and the display panel DP may be performed before the curing process. Thus, the low-adhesion part SC and the high-adhesion part HC may serve to temporarily fix the position of the sensor FS in a process that is performed before the curing process is performed, such as the autoclave process.

In a display device according to a comparative example, an adhesion part is disposed on each corner of the sensor over the sensor and the cover panel to fix the position of the sensor. Thereafter, the adhesion part is cured by ultraviolet rays, and the sensor is temporarily coupled to the cover panel, so that the position of the sensor is fixed. In the display device according to the comparative example, the adhesion part for temporary coupling remains on the sensor, and a thickness of the adhesion part causes various undesired effects to the display device. For example, a design margin such as a thickness of the sensor or a depth of the seating groove is reduced as much as the thickness of the adhesion part. Also, due to the thickness of the adhesion part, direct or indirect pressure is applied to components overlapping the sensor on the plane, and reliability of the display device is degraded.

According to an embodiment, the high-adhesion part HC may be disposed between the first protective layer PL1 and the second protective layer PL2. The high-adhesion part HC may strongly couple the first protective layer PL1 and the second protective layer PL2 with high strength to be fixed.

According to an embodiment of the invention, the sensor FS may be temporarily coupled to the second protective layer PL2 through the low-adhesion part SC to be temporarily fixed in position, and the second protective layer PL2 may be coupled to the first protective layer PL1 through the high-adhesion part HC to be fixed in position. Thereafter, the first protective layer PL1, the low-adhesion part SC, and the high-adhesion part HC may be removed during the process for manufacturing the display device, and the display device may have improved reliability.

According to an embodiment, the low-adhesion part SC may have an integrated shape or a shape integrally formed as a single unitary indivisible part.

In an embodiment, the second protective layer PL2 may have a thickness greater than a thickness (or an entire thickness) of the first protective layer PL1.

According to an embodiment, the second protective layer PL2 may have a thickness of about 100 micrometers (µm) or greater to stably secure the position of the sensor FS that is not permanently coupled.

According to an embodiment, the high-adhesion part HC may include a first sub-adhesion part HC1 and a second sub-adhesion part HC2, which are spaced apart from each other.

As illustrated in FIG. 3, the first sub-adhesion part HC1 may contact the first sub-protective layer PL1-1 of the first protective layer PL1, and the second sub-adhesion part HC2 may contact the second sub-protective layer PL1-2 of the first protective layer PL1. However, the embodiment of the invention is not limited thereto. In an embodiment, for example, the first sub-adhesion part HC1 and the second sub-adhesion part HC2 may contact at least one selected from the first sub-protective layer PL1-1 and the second sub-protective layer PL1-2 depending on positions thereof. Detailed features thereof will be described later.

The connector CN may be disposed on the control unit CM and the first protective layer PL1. The connector CN may have one end connected to the control unit CM and an opposing end protruding from one side of the display panel DP. The connector CN may electrically connect the display panel DP to external test equipment (not shown). The connector CN may be used in a test process for checking an operation of the display panel DP.

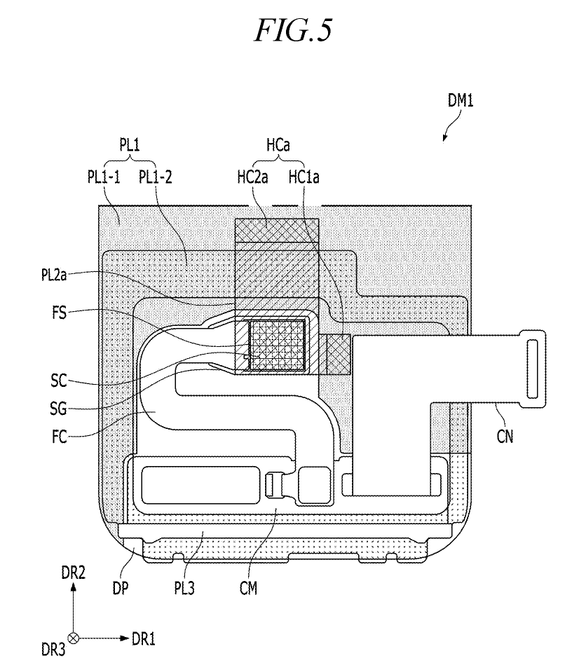

FIG. 5 is a plan view illustrating a display module according to an embodiment.

Referring to FIG. 5, a display module DM1 according to an embodiment may include a second protective layer PL2a and a high-adhesion part HCa. The high-adhesion part HCa may include a first sub-adhesion part HC1a and a second sub-adhesion part HC2a. The second protective layer PL2a may extend in the second direction DR2 to overlap the first sub-protective layer PL1-1 and the second sub-protective layer PL1-2. The second sub-adhesion part HC2a may be disposed between the first sub-protective layer PL1-1 and the second protective layer PL2a to couple the first sub-protective layer PL1-1 and the second protective layer PL2a to each other. The sensor FS may be temporarily coupled to the second protective layer PL2a through the low-adhesion part SC to be temporarily fixed in position, and the second protective layer PL2a may be coupled to the first protective layer PL1 through the high-adhesion part HCa to be fixed in position.

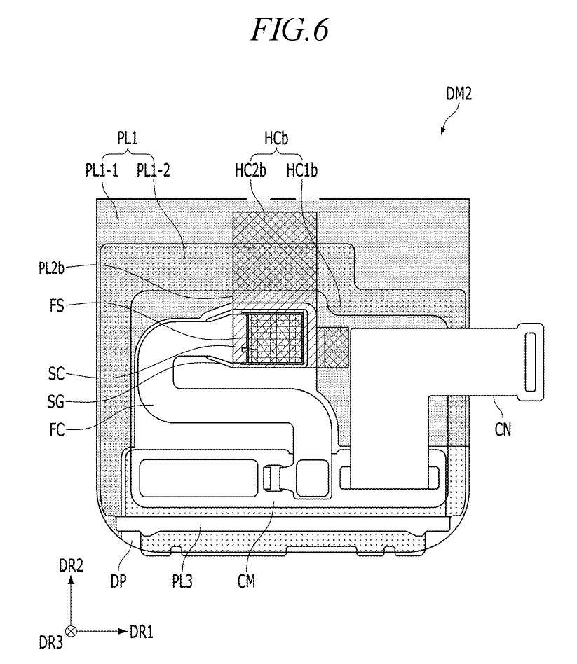

FIG. 6 is a plan view illustrating a display module according to an embodiment.

Referring to FIG. 6, a display module DM2 according to an embodiment may include a second protective layer PL2b and a high-adhesion part HCb. The high-adhesion part HCb may include a first sub-adhesion part HC1b and a second sub-adhesion part HC2b. The second protective layer PL2b may extend in the second direction DR2 to overlap the first sub-protective layer PL1-1 and the second sub-protective layer PL1-2. The second sub-adhesion part HC2b may extend from a portion of the first sub-protective layer PL1-1 to the second sub-protective layer PL1-2 to overlap the first sub-protective layer PL1-1 and the second sub-protective layer PL1-2 on the plane. The sensor FS may be temporarily coupled to the second protective layer PL2b through the low-adhesion part SC to be temporarily fixed in position, and the second protective layer PL2b may be coupled to the first protective layer PL1 through the high-adhesion part HCb to be fixed in position.

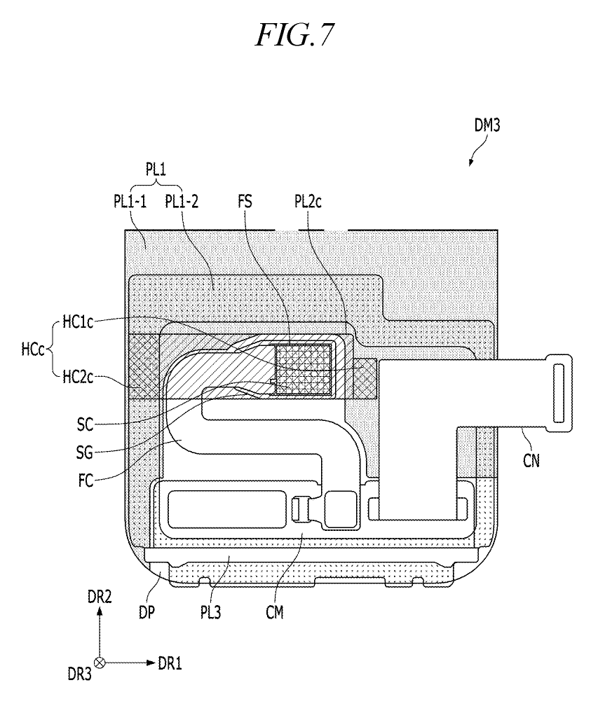

FIG. 7 is a plan view illustrating a display module according to an embodiment.

Referring to FIG. 7, a display module DM3 according to an embodiment may include a second protective layer PL2c and a high-adhesion part HCc. The high-adhesion part HCc may include a first sub-adhesion part HC1c and a second sub-adhesion part HC2c. The second protective layer PL2c may extend in the first direction DR1. The first sub-adhesion part HC1c and the second sub-adhesion part HC2c may be spaced apart from each other with the sensor FS therebetween. The first sub-adhesion part HC1c may be disposed between the first sub-protective layer PL1-1 and the second protective layer PL2c, and the second sub-adhesion part HC2c may be disposed between the second sub-protective layer PL1-2 and the second protective layer PL2c. The sensor FS may be temporarily coupled to the second protective layer PL2c through the low-adhesion part SC to be temporarily fixed in position, and the second protective layer PL2c may be coupled to the first protective layer PL1 through the high-adhesion part HCc to be fixed in position.

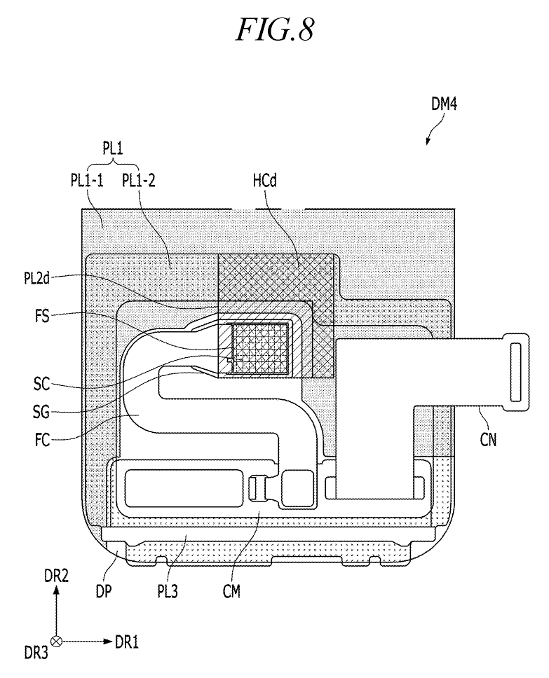

FIG. 8 is a plan view illustrating a display module according to an embodiment.

Referring to FIG. 8, a display module DM4 according to an embodiment may include a second protective layer PL2d and a high-adhesion part HCd. The high-adhesion part HCd may be integrally formed as a single unitary indivisible part to contact the first sub-protective layer PL1-1, the second sub-protective layer PL1-2, and the second protective layer PL2d. The sensor FS may be temporarily coupled to the second protective layer PL2d through the low-adhesion part SC to be temporarily fixed in position, and the second protective layer PL2d may be coupled to the first protective layer PL1 through the high-adhesion part HCd to be fixed in position.

According to embodiments described with reference to FIGS. 5 to 8, the sensor may be temporarily coupled to the second protective layer through the low-adhesion part to be temporarily fixed in position, and the second protective layer may be coupled to the first protective layer through the high-adhesion part to be fixed in position. Thereafter, the first protective layer, the low-adhesion part, and the high-adhesion part may be removed during the process for manufacturing the display device, and the display device may have improved reliability. Thus, the embodiments described with reference to FIGS. 5 to 8 may have same effect as the display module described with reference to FIG. 3, while having greater design flexibility and various shapes.

The display device according to an embodiment of the invention may be applied to various electronic devices. An electronic device according to an embodiment may include the above-described display device and further include a module or device having an additional function.

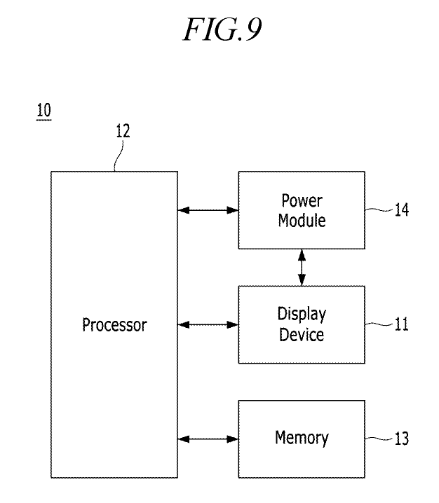

FIG. 9 is a block diagram illustrating an electronic device according to an embodiment. Referring to FIG. 9, an electronic device 10 according to an embodiment may include a display device 11, a processor 12, a memory 13, and a power module 14.

The processor 12 may include at least one selected from a central processing unit (CPU), an application processor (AP), a graphics processing unit (GPU), a communication processor (CP), an image signal processor (ISP), or a controller.

The memory 13 may store data information used for an operation of the processor 12 or the display device 11. When the processor 12 executes an application stored in the memory 13, an image data signal and/or an input control signal may be transmitted to the display device 11, and the display device 11 may process the received signal to output image information through a display screen.

The power module 14 may include a power supply module, such as a power adapter or a battery device, and a power conversion module that converts power supplied by the power supply module to generate power used for an operation of the electronic device 10.

At least one of the above-described components of the electronic device 10 may be contained in the display device according to the above-described embodiments. Also, some of the individual modules functionally included in a single module may be contained in the display device, and some thereof may be provided separately from the display device.

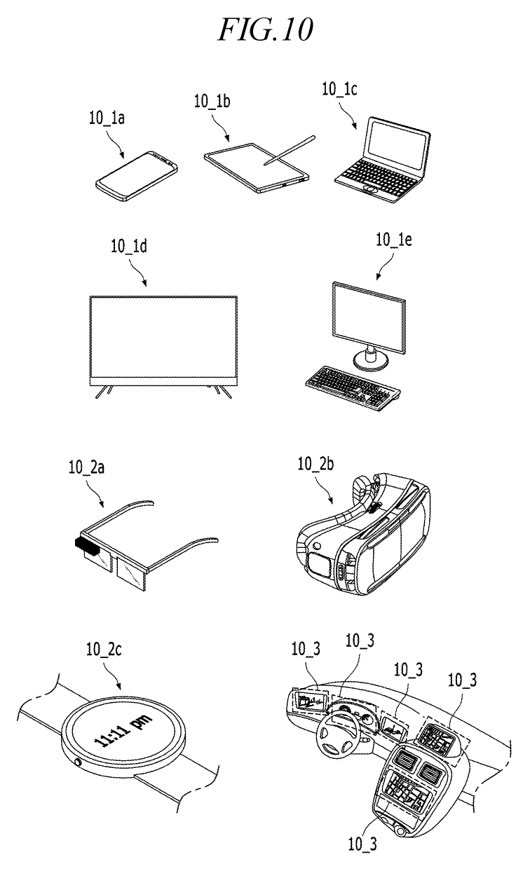

FIG. 10 is schematic views illustrating electronic devices according to various embodiments.

Referring to FIG. 10, various electronic devices to which the display devices according to embodiments are applied may include an image display electronic device, such as a smartphone 10_1a, a tablet personal computer (PC) 10_1b, a laptop computer 10_1c, a television (TV) 10_1d, and a desktop monitor 10_1e, a wearable electronic device including a display module, such as smart glasses 10_2a, a head-mounted display 10_2b, and a smartwatch 10_2c, and a vehicle electronic device 10_3, such as an vehicle dashboard, a center fascia, a center information display (CID) disposed on a dashboard, and a room mirror display.

According to embodiment of the invention, since the residual materials may not remain on the sensor after being attached to the display panel, the display module and the electronic device with improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module comprising:
a display panel;
a first protective layer disposed on the display panel;
a sensor disposed on the display panel not to overlap the first protective layer in a plan view;
a control unit disposed on the display panel and electrically connected to the display panel;
a flexible circuit connected to the sensor and the control unit;
a second protective layer disposed on the first protective layer and the sensor to cover the sensor;
a high-adhesion part disposed between the first protective layer and the second protective layer; and
a low-adhesion part disposed between the second protective layer and the sensor,
wherein the low-adhesion part has an integrated shape.

2. The display module of claim 1, wherein the first protective layer comprises:
a first sub-protective layer disposed on at least a portion of the display panel; and
a second sub-protective layer disposed on another portion of the display panel and at least a portion of the first sub-protective layer,
wherein the second sub-protective layer covers an area corresponding to a driver integrated circuit of the display panel in the plan view.

3. The display module of claim 2, further comprising a cushion layer disposed on the second sub-protective layer,
wherein the cushion layer overlaps the area corresponding to the driver integrated circuit of the display panel in the plan view.

4. The display module of claim 2, wherein the high-adhesion part contacts the second protective layer and at least one selected from the first sub-protective layer and the second sub-protective layer.

5. The display module of claim 1, wherein the high-adhesion part comprises a first sub-adhesion part and a second sub-adhesion part, which are spaced apart from each other.

6. The display module of claim 5, wherein the first sub-adhesion part contacts the first sub-protective layer and the second protective layer, and
the second sub-adhesion part contacts the second sub-protective layer and the second protective layer.

7. The display module of claim 5, wherein the first sub-adhesion part contacts the first sub-protective layer, the second sub-protective layer, and the second protective layer, and
the second sub-adhesion part contacts the first sub-protective layer and the second protective layer.

8. The display module of claim 5, wherein the first sub-adhesion part and the second sub-adhesion part are spaced apart from each other with the sensor therebetween.

9. The display module of claim 1, wherein the high-adhesion part is disposed on the first protective layer and the second protective layer, and
the high-adhesion part has an integrated shape.

10. The display module of claim 1, wherein the sensor is a fingerprint sensor.

11. The display module of claim 1, wherein the second protective layer has a thickness greater than a thickness of the first protective layer.

12. The display module of claim 1, wherein the second protective layer has a thickness of about 100 μm or greater.

13. The display module of claim 1, wherein the low-adhesion part is in contact with the sensor and is not in contact with the display panel.

14. The display module of claim 1, wherein the second protective layer comprises at least one selected from polyethylene terephthalate (PET), polyethylene (PE), and polyimide (PI).

15. A display module comprising:
a display panel;
a first protective layer disposed on the display panel;
a sensor disposed on the display panel not to overlap the first protective layer in a plan view;
a control unit disposed on the display panel and electrically connected to the display panel;
a flexible circuit connected to the sensor and the control unit;
a second protective layer disposed on the first protective layer and the sensor to cover the sensor;
a high-adhesion part disposed between the first protective layer and the second protective layer; and
a low-adhesion part disposed between the second protective layer and the sensor,
wherein the second protective layer has a thickness greater than a thickness of the first protective layer.

16. The display module of claim 15, wherein the sensor is a fingerprint sensor.

17. The display module of claim 15, wherein the low-adhesion part is in contact with the sensor and is not in contact with the display panel.

18. The display module of claim 15, wherein the second protective layer has a thickness of about 100 μm or greater.

19. A display module comprising:
a display panel;
a first sub-protective layer disposed on at least a portion of the display panel;
a second sub-protective layer disposed on another portion of the display panel and at least a portion of the first sub-protective layer;
a sensor disposed on the display panel not to overlap the first sub-protective layer and the second sub-protective layer in a plan view;
a second protective layer disposed on the first sub-protective layer, the second sub-protective layer, and the sensor to cover the sensor;
a high-adhesion part disposed between the second protective layer and at least one selected from the first sub-protective layer and the second sub-protective layer; and
a low-adhesion part disposed between the second protective layer and the sensor,
wherein the low-adhesion part has an integrated shape.

20. The display module of claim 19, wherein the sensor is a fingerprint sensor, and
the second sub-protective layer covers an area corresponding to a driver integrated circuit of the display panel in the plan view.
